(19) United States
(12) Patent Application Publication
(10) Pub. No.: US 2008/0191721 A1
(43) Pub. Date: Aug. 14, 2008

(54) Electrical test device for testing electrical test pieces

(75) Inventors: Gunther Bohm, Nufringen (DE); Peter Stolp, Ammerbuch (DE); Georg Steidle, Waldenbuch (DE)

Correspondence Address: HARNESS, DICKEY & PIERCE, P.L.C., P.O. BOX 828, BLOOMFIELD HILLS, MI, 48303, US

(73) Assignee: Feinmetall GmbH, Herrenberg (DE)

(21) Appl. No.: 12/069,053

(22) Filed: Feb. 7, 2008

(30) Foreign Application Priority Data
Feb. 8, 2007 (DE) 10 2007 007 741.8
Jan. 17, 2008 (DE) 10 2008 004 800.3

(51) Int. Cl. G01R 31/02

(52) U.S. Cl. 324/754

(57) ABSTRACT

The invention relates to an electrical test device for testing electrical test pieces comprising at least one electrical contact system and at least one electrical connecting device provided with at least one electrical/electronic component, and having contact surfaces for touch contacting of the contact system which may be contacted by the test piece, and having a wiring substrate and a connecting element; wherein the electrical/electronic component is carried by the connecting element.

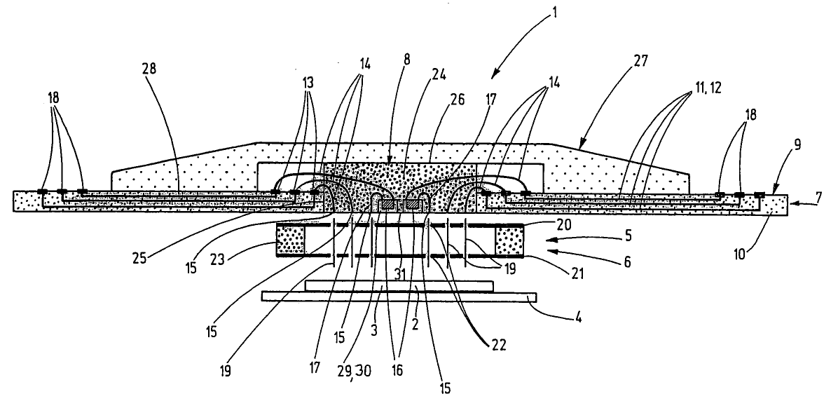

### CROSS-REFERENCE TO RELATED APPLICATIONS

This application claims the benefit of DE 10 2007 007 741.8, filed Feb. 8, 2007 and DE 10 2008 004 800.3, filed Jan. 17, 2008. The disclosures of the above applications are incorporated herein by reference.

### FIELD

The present disclosure relates to an electrical test device for testing electrical test pieces, preferably wafers, comprising at least one electrical contact system and at least one electrical connecting device provided with at least one electrical/electronic component and having contact surfaces for touch contacting of the contact system which may be contacted by the test piece, and having a wiring substrate and a connecting element.

### BACKGROUND

The statements in this section merely provide background information related to the present disclosure and may not constitute prior art.

Electrical test devices of the aforementioned type are used to electrically contact a test piece to test its functionality. The electrical test device establishes electrical connections with the test piece; i.e., the electrical test device on the one hand contacts electrical connections of the test piece, and on the other hand provides electrical contacts which are connected to a test system, which by means of the test device sends electrical signals to the test piece in order to perform function testing, for example resistance measurements, current and voltage measurements, and so forth. Since the electrical test piece often is an extremely small electronic component such as a wafer, the contact system has correspondingly sized contact elements. To provide the opportunity for electrical connection with the referenced test system, the contact elements of the contact system are in touch contact with a connecting device, which among other things increases the contact distance and in this manner enables the connection of electrical connecting cables which lead to the test system. In the so-called “wired test card,” wires lead from the contact surfaces and/or to electrical/electronic components located on the wiring substrate. These electrical/electronic components ensure the functionality of the test card; i.e., they impart appropriate electrical properties. The electrical/electronic components are soldered onto the wiring substrate, which in particular is designed as a printed circuit board.

Under certain test conditions limitations may result in the known electrical test devices, for example when the testing is performed at very high electrical frequencies.

### SUMMARY

The object of the invention, therefore, is to provide an electrical test device of the type referenced at the outset which allows the test piece to be reliably tested, even under extreme test conditions.

Further areas of applicability will become apparent from the description provided herein. It should be understood that the description and specific examples are intended for purposes of illustration only and are not intended to limit the scope of the present disclosure.

This object is achieved according to the invention by the fact that the electrical/electronic component is located in/on the connecting element. Due to the design according to the invention, the length of the line between the test piece and the electrical/electronic component is significantly reduced because the component is located in/on the connecting element. The connecting element is placed very close to the test piece; only the contact system is located between the test piece and the connecting element. The effectiveness and functionality of the electrical component are greatly increased as a result of the very short line length between the electrical/electronic component and the test piece. Thus, the test piece may also be tested in particular at very high electrical frequencies. The position of the electrical component in/on the connecting element is not only very close to the test piece, but is also preferably provided in an area which is basically reserved for the configuration of contacts of the contact system, resulting in a special feature as the result of this measure. In particular, the subject matter of the invention involves a “wired test card.”

The connecting element is preferably designed as a connecting housing or connecting plate, and the electrical/electronic component is preferably located in/on the connecting housing or in/on the connecting plate.

According to one refinement of the invention, the connecting element, which in particular is designed as a connecting housing or connecting plate, has at least one receptacle for accommodating the component. The electrical/electronic component may preferably be designed as a surface mount technology (SMT) component.

According to one refinement of the invention, the connecting element, which in particular is designed as a connecting housing or connecting plate, contains the contact surfaces. As a result, the at least one electrical/electronic component may be situated in the immediate vicinity of the contact surfaces, whereby via the contact system the contact surfaces may be brought into touch contact with the test piece.

The wiring substrate is designed in particular as a printed circuit board.

In one refinement of the invention, the wiring substrate has an opening in which the connecting element, which preferably is designed as a connecting housing or connecting plate, is located, at least in places. The opening is used to accommodate the connecting element; i.e., the connecting element is enclosed by the wiring substrate, in particular the printed circuit board. The connecting element is preferably in a central configuration with respect to the wiring substrate; i.e., the opening is centrally or essentially centrally located in the wiring substrate.

According to one refinement of the invention, the receptacle is designed as a recess or a cutout. By means of the recess or cutout the component is protectively accommodated while still allowing external access for replacement of the component in the event of a defect, for example.

The contact system is preferably designed as a contact head. As contacts, the contact system preferably has contact pins, in particular bent needles, which at their one end are able to contact the contact surfaces and at their other end are able to contact the test piece. These contacts are preferably touch contacts.

The configuration may be designed in such a way that at least one contact surface is electrically connected to the component. It is further preferred that at least one conductor of the wiring substrate is electrically connected to the component. Depending on the design, the component may be electrically connected to the at least one contact surface either directly or via a connecting line. Furthermore, the conductor of the wiring substrate may be connected to the component, either directly or via a connecting line.

In one refinement of the invention, the receptacle or at least one of the receptacles is provided on a side of the connecting element, in particular the connecting housing or connecting plate, facing toward the contact system and/or on a side of the connecting element facing away from the contact system. The receptacle for the component may thus be provided on the side of the connecting element facing toward the test piece or on the side of the connecting element facing away from the test piece. The configuration is designed in such a way that in any case the component is accessible for replacement as needed.

According to one refinement of the invention, the receptacle is provided in a region which is free of contact surfaces, adjacent to at least one contact surface. Although the region in which the component is located is basically reserved for contacts of the contact system, the invention makes a departure and provides the component at that location, preferably between the contacts of the contact system, such that it does not have an objectionable appearance.

A support device is preferably associated with the connecting element. Since for the touch contacting of the test piece to be tested each of the contacts of the contact system is supported at one end on the test piece and at the other end on the contact surface of the connecting element to be contacted, upon each contact a contact force occurs, which for the plurality of contacts is summed to produce an overall high contact force. The support device is provided to allow this high contact force to be absorbed without impermissible deformation of modules of the test device. The support device is a relatively rigid component (stiffener) on which the connecting element is supported.

The support device preferably has at least one access opening for accessing the at least one component. The support device is consequently designed in such a way that the access opening provides access to the component so that, for example, the component may be replaced as needed.

### DRAWINGS

The drawing illustrates the invention with reference to one exemplary embodiment; the FIGURE shows a schematic longitudinal section of an electrical test device. The drawing described herein is for illustration purposes only and is not intended to limit the scope of the present disclosure in any way.

### DETAILED DESCRIPTION

The following description is merely exemplary in nature and is not intended to limit the present disclosure, application, or uses.

The FIGURE schematically shows a longitudinal section of an electrical test device 1 used for the electrical touch contacting of an electrical test piece 2. The test device 1 is connected via electrical cable connections (not illustrated) to a test system (likewise not illustrated) in order to subject the test piece 2 to electrical testing. The test piece 2, which in particular may be designed as a wafer 3, is located on a supporting base 4. The test piece 2 has connecting points (not illustrated in greater detail) which may be touch-contacted for the test by means of the electrical test device 1. For this purpose the test piece 2 and the electrical test device 1 are moved relative to one another.

The test device 1 has a contact system 5 which is designed as a contact head 6. The test device 1 also has a connecting device 7 which has a connecting element 8 and a wiring substrate 9. The wiring substrate 9 is designed as a printed circuit board 10, in particular a multilayer printed circuit board 10. The printed circuit board has conductors 11 which preferably are designed as printed conductors 12 and which at their ends facing away from the contact head 6 have contact surfaces 13 which via electrical connecting lines 14 lead to contact surfaces 15 or to electrical/electronic components 16. The contact surfaces 15 are formed in particular by the end faces of the connecting conductors 14, which preferably are designed as wire connections. Connecting lines 17 are also provided which lead from the components 16 to contact surfaces 15. At their other, radially outwardly situated ends the conductors 11 have electrical connecting surfaces 18 which may be connected to the test system (not illustrated) via the referenced cable connections (not illustrated). The configuration is designed in such a way that the connecting device forms a converting device; i.e., the very small distance between the very small contact surfaces 15 (having a diameter of 50 to 300 μm, for example) is converted to larger distances between the connecting surfaces 18 by means of the connecting conductors 14 and the conductors 11. The size of the connecting surfaces in each case allows contact to be easily established with the cable connections (not illustrated). The contact head 6 is provided with a plurality of oblong contacts 19 which are mounted so as to be longitudinally displaceable, and which may preferably be designed as contact needles, in particular bent needles, which with their one end regions are associated with the test piece 2, and with their other end regions are associated with the connecting device 7.

During testing of the test piece 2 the test device 1 moves in the direction of the test piece 2, and/or the test piece 2 moves in the direction of the test device 1, so that the end faces of the contacts 19 meet the test piece 2 and also the contact surfaces 15. Proper contacting is possible due to the fact that the contacts 19 are designed in particular as bent wires; i.e., they have a slightly elastic design in the axial direction as the result of bending. The contact head 6 has two interspaced parallel ceramic plates 20, 21 which are provided with bearing holes 22 for accommodating the contacts 19. The parallel separation distance between the two ceramic plates 20 and 21 is achieved by means of a spacer 23.

The connecting conductors 14 extend, at least in sections, through the connecting element 8 and are fixed in place at that location. According to the illustrated exemplary embodiment the connecting element 8 may be designed as a connecting housing 24. The connecting housing is implemented as a cast block, for example, in which the connecting conductors 14 are cast in a fixed position. The wiring substrate 9 has an opening 25 in which sections of the connecting element 8 are located. The connecting element 8 has an upper side 26 which is supported on a support device 27. The support device 27 is designed as a rigid component, so that the contact forces originating from the contacts 19 may be absorbed without deformation of the components of the electrical test device 1. The wiring substrate 9 has an upper side 28 which is likewise supported on the support device 27.

According to a further exemplary embodiment (not illustrated), the support element 8 may also have a flat design, so that it forms a connecting plate instead of a connecting housing 24.

Regardless of whether it is designed as a connecting housing 24 or as a connecting plate, the connecting element 8 contains the contact surfaces 15 which are connected to the connecting conductors 14 or 17, or which are formed by the end faces of these connecting conductors 14,17. Furthermore, at least one electrical/electronic component 16, a capacitor, for example, is associated with the connecting element 8; i.e., the component 16 is located in or on the connecting element 8. As illustrated in the exemplary embodiment in the FIGURE, at that location the component may be situated in a receptacle 29. The receptacle 29 is a recess 30 which is provided on the underside 31 of the connecting element 8. In the illustrated exemplary embodiment, two receptacles 29, for example, are provided which are designed as recesses 30, each accommodating one component 16. On account of the configuration of the components 16 in the connecting element, the connecting conductors 17 are very short; i.e., the components 16 are positioned very close to the test piece 2, so that the electrical connecting paths between the component 16 and the test piece 2 are so short that in particular measurements are possible even at very high frequencies. The electrical functionality of the components 16 is thus always ensured. Furthermore, external test conditions may be realized which are not possible at all for electrical/electronic components connected via longer line connections.

Due to the configuration of the electrical/electronic component 16 in the region of one of the outer sides of the connecting element 8, in particular at the underside 31 or the upper side 26, in a recess 30 or in a nonrecessed position, external access to the component 16 is always provided so that the component may be replaced as needed. The electrical/electronic component 16 may be designed as a surface mount technology (SMT) component. Alternatively, it is also possible to design the component 16 in such a way that it has its own connecting wires, which with a sufficient length may be directly connected to the contact surfaces 13 if needed, or may form the contact surfaces 15.

If the electrical/electronic component 16 is located on the upper side 26 of the connecting elements 8 or in the vicinity of the upper side 26, for example in a recess 30, the support device 27 is preferably provided with an access opening which allows external access to the component 16. This embodiment is not illustrated in the FIGURE.

Mention of one or more electrical/electronic components 16 herein does not limit the number of components, since the invention depends not on the presence of one or more components 16, but, rather, depends in particular on the special positioning of the component 16 or components 16.

What is claimed is:

1. An electrical test device for testing electrical test pieces comprising:
at least one electrical contact system; and
at least one electrical connecting device provided with at least one electrical/electronic component and having contact surfaces for touch contacting of the contact system which may be contacted by the test piece, and having a wiring substrate and a connecting element;
wherein the electrical/electronic component is carried by the connecting element.

2. The test device according to claim 1, wherein the connecting element is designed as one of a connecting housing and a connecting plate, and the electrical/electronic component is carried by one of the connecting housing and the connecting plate.

3. The test device according to claim 1, wherein the connecting element has at least one receptacle for accommodating the component.

4. The test device according to claim 1, wherein the connecting element contains the contact areas.

5. The test device according to claim 1, wherein the wiring substrate is designed as a printed circuit board.

6. The test device according to claim 1, wherein the wiring substrate has an opening in at least one place in which the connecting element is located.

7. The test device according to claim 3, wherein the receptacle is designed as a recess or a cutout.

8. The test device according to claim 1, wherein the contact system is a contact head.

9. The test device according to claim 1, wherein the contact system has contact pins which at their one end make touch contact with the contact surfaces and at their other end may make touch contact with the test piece.

10. The test device according to claim 1, wherein at least one contact surface is electrically connected to the component.

11. The test device according to claim 1, wherein at least one conductor of the wiring substrate is electrically connected to the component.

12. The test device according to claim 1, wherein the component is connected to at least one electrical connecting line in the form of an electrical wire.

13. The test device according to claim 3, wherein at least one of the receptacles is provided on a side of the connecting element facing toward the contact system and/or on a side of the connecting element facing away from the contact system.

14. The test device according to claim 3, wherein the receptacle is provided in a region which is free of contact surfaces, adjacent to at least one contact surface.

15. The test device according to claim 1, wherein a support device is associated with the connecting element.

16. The test device according to claim 15, wherein the support device is provided on a side of the connecting element facing away from the contact system.

17. The test device according to claim 15, wherein the support device has at least one access opening for accessing the component.
